(19) United States
(12) Patent Application Publication
(10) Pub. No.: US 2022/0262775 A1
(43) Pub. Date: Aug. 18, 2022

(54) LIGHT-EMITTING DIODE LIGHT-EMITTING BACKPLANE AND MANUFACTURING METHOD THEREOF

(71) Applicant: CHONGQING KONKA PHOTOELECTRIC TECHNOLOGY RESEARCH INSTITUTE CO., LTD., Chongqing (CN)

(72) Inventors: Jiahua HUANG, Chongqing (CN); Pengyue ZHANG, Chongqing (CN)

(21) Appl. No.: 17/734,583

(22) Filed: May 2, 2022

Related U.S. Application Data
(63) Continuation of application No. PCT/CN2020/093013, filed on May 28, 2020.

(51) Int. Cl. H01L 25/075; H01L 33/58; H01L 33/52

(52) U.S. Cl. CPC H01L 25/0753; H01L 33/58; H01L 2933/0058; H01L 2933/005; H01L 33/52

(57) ABSTRACT

A light-emitting diode (LED) light-emitting backplane and a manufacturing method for an LED light-emitting backplane are provided. The LED light-emitting backplane includes a drive backplane (100) mounted with more than two LED chips (101), an upper end face of each of the more than two LED chips is covered with a light-transmitting layer (104), and an optical isolation material (102) is filled between the drive backplane and the light-transmitting layer.

### CROSS-REFERENCE TO RELATED APPLICATIONS

This application is a continuation of International Application No. PCT/CN2020/093013, filed on May 28, 2020 the entire disclosure of which is incorporated herein by reference.

### TECHNICAL FIELD

This disclosure relates to the technical field of light-emitting diode (LED), and in particular, to an LED light-emitting backplane and a manufacturing method for an LED light-emitting backplane.

### BACKGROUND

With development of scientific technologies, light-emitting diodes (LEDs) are widely applied to display devices due to their several advantages such as good stability, long service life, low power consumption, high color saturation, fast response speed, strong contrast, and the like.

### Technical Problem

An existing encapsulation manner for light-emitting diode (LED) displays is mainly to mix resin and carbon powder and then encapsulate in a die forming manner, to enable LED chips to be covered with an encapsulation layer. The carbon powder is also mixed in encapsulation areas corresponding to light-emitting surfaces of the LED chips in the encapsulation layer, which extremely affects a light transmittance of each of the LED chips and results in a reduction of overall brightness by more than 70%, thereby affecting overall brightness of products.

### SUMMARY

An LED light-emitting backplane is provided in the disclosure.

The LED light-emitting backplane includes a drive backplane mounted with more than two LED chips, where an upper end face of each of the more than two LED chips is covered with a light-transmitting layer, and an optical isolation material is filled between the drive backplane and the light-transmitting layer.

A manufacturing method for an LED light-emitting backplane is further provided in the disclosure. The manufacturing method includes the following.

A drive backplane is provided, and more than two LED chips are welded on electrodes of the drive backplane. An optical isolation material is coated on a side of the drive backplane carrying the more than two LED chips, to enable a thickness of the optical isolation material to be equal to a height of each of the more than two LED chips. A light-transmitting layer is formed by covering upper end faces of all the more than two LED chips with a pre-prepared light-transmitting film and fixing the light-transmitting film on each of the more than two LED chips.

### BRIEF DESCRIPTION OF THE DRAWINGS

For ease of illustration, the disclosure will be illustrated in detail with reference of the following better implementations and the accompanying drawings.

FIG. 1 is a schematic cross-sectional structural diagram of a light-emitting diode (LED) light-emitting backplane provided in an implementation of the disclosure.

FIG. 2 is a schematic cross-sectional structural diagram of an LED light-emitting backplane provided in another implementation of the disclosure.

FIG. 3 is a schematic cross-sectional structural diagram of an LED light-emitting backplane provided in a yet another implementation of the disclosure.

FIG. 4 is a schematic flow chart illustrating a manufacturing method for an LED light-emitting backplane provided in an implementation of the disclosure.

FIG. 5 is a schematic flow chart illustrating a manufacturing method for an LED light-emitting backplane provided in another implementation of the disclosure.

Description for reference signs of the accompanying drawings: 100—drive backplane; 101—LED chip; 102—optical isolation material; 103—semitransparent layer; 104—high light-transmitting layer.

### DETAILED DESCRIPTION

In order to make the purposes, technical solutions, and advantages of the present disclosure clearer, the following will describe the present disclosure in detail with a combination of accompanying drawings and implementations. It should be understood that, specific implementations described herein are merely for explaining, rather than limiting, the present disclosure.

In description of the disclosure, it should be understood that locations or positional relationships indicated by terms such as “center”, “longitudinal”, “lateral”, “length”, “width”, “thickness”, “on”, “under”, “front”, “back”, “left”, “right”, “vertical”, “horizontal”, “top”, “bottom”, “in”, “out”, “clockwise”, “anticlockwise”, and the like are locations or positional relationship based on accompanying drawings and are only for the convenience of description and simplicity, rather than explicitly or implicitly indicate that apparatuses or components referred to herein must have a certain direction or be configured or operated in a certain direction and therefore cannot be understood as limitations to the disclosure. In addition, terms “first”, “second”, and the like are only used for description and cannot be understood as explicitly or implicitly indicating relative importance or implicitly indicating the number of technical features referred to herein. Therefore, features limited by terms “first”, “second”, and the like can explicitly or implicitly include at least one of the features. In the context of the present disclosure, unless stated otherwise, “multiple” or “a plurality of” refers to “at least two”.

In description of the present disclosure, it should be noted that, unless stated otherwise, terms “installing”, “coupling”, and “connecting” referred to herein should be understood in broader sense. For example, they may include a fixed coupling, a removable coupling, or an integrated coupling; they may include a mechanical coupling or an electrical coupling; they may include a direct coupling, an indirect coupling through a medium, or an interconnection between two components, or an interaction coupling between two components. For those of ordinary skill in the art, the above terms in the present disclosure can be understood according to specific situations.

In the related art, resin and carbon powder are mixed to be encapsulated in an encapsulation layer, resulting in a low light transmittance of a light-emitting diode (LED) chip, thereby affecting overall brightness of an LED light-emitting backplane.

Based on the above, a solution is provided in the disclosure, to solve the above-mentioned technical problems. The solution will be explained in detail in the following implementations.

In order to overcome the above-mentioned defects, the disclosure aims to provide a light-emitting diode (LED) light-emitting backplane and a manufacturing method for the LED light-emitting backplane, which can improve display brightness and a display effect.

The aims of the disclosure are implemented through the following technical solutions.

An LED light-emitting backplane is provided in the disclosure.

The LED light-emitting backplane includes a drive backplane mounted with more than two LED chips, where an upper end face of each of the more than two LED chips is covered with a light-transmitting layer, and an optical isolation material is filled between the drive backplane and the light-transmitting layer.

For the LED light-emitting backplane in the disclosure, the optical isolation material is disposed between two adjacent LED chips of the more than two LED chips, and the upper end face of each of the more than two LED chips is covered with the light-transmitting layer. Through the encapsulation manners of respectively disposing the optical isolation material and the light-transmitting layer, an effect of the optical isolation material on a light transmittance of the light-transmitting layer can be effectively avoided, a light transmittance of each of the more than two LED chips can be effectively improved, thereby improving overall brightness of a product.

Optionally, the light-transmitting layer includes a semitransparent layer and/or a high light-transmitting layer.

Optionally, the high light-transmitting layer has a light transmittance greater than the semitransparent layer.

Optionally, the semitransparent layer has a light transmittance ranging from 30% to 80%.

Optionally, the high light-transmitting layer has a light transmittance greater than 90%.

Optionally, the semitransparent layer covers each of the more than two LED chips, and the high light-transmitting layer is disposed on a side of the semitransparent layer away from each of the more than two LED chips.

Optionally, the optical isolation material has a height shorter than each of the more than two LED chips.

Optionally, the optical isolation material consists of a black optical isolation material.

Optionally, the optical isolation material is doped with a thermally conductive particle.

Optionally, the optical isolation material consists of a white optical isolation material.

Based on the same conception, a manufacturing method for an LED light-emitting backplane is further provided in the disclosure. The manufacturing method includes the following.

A drive backplane is provided, and more than two LED chips are welded on electrodes of the drive backplane. An optical isolation material is coated on a side of the drive backplane carrying the more than two LED chips, to enable a thickness of the optical isolation material to be equal to a height of each of the more than two LED chips. A light-transmitting layer is formed by covering upper end faces of all the more than two LED chips with a pre-prepared light-transmitting film and fixing the light-transmitting film on each of the more than two LED chips.

For the manufacturing method for an LED light-emitting backplane in the disclosure, the optical isolation material and the light-transmitting layer are respectively disposed on an external side of each of the more than two LED chips, such that a manufactured LED light-emitting backplane can effectively avoid an effect of the optical isolation material on a light transmittance of the light-transmitting layer and effectively improve a light transmittance of each of the more than two LED chips, thereby improving overall brightness of a product.

Optionally, after coating the optical isolation material on the side of the drive backplane carrying the more than two LED chips, and before covering the upper end faces of all the more than two LED chips with the pre-prepared light-transmitting film, the method further includes plasma cleaning a surface of each of the more than two LED chips.

Optionally, after coating the optical isolation material on the side of the drive backplane carrying the more than two LED chips, and before plasma cleaning the surface of each of the more than two LED chips, the method further includes the following. A first round of heating is performed on the drive backplane for a first heating duration, to pre-cure the optical isolation material on the drive backplane.

Optionally, the light-transmitting layer is formed by covering the upper end faces of all the more than two LED chips with the pre-prepared light-transmitting film and fixing the light-transmitting film on each of the more than two LED chips as follows.

The light-transmitting film is provided and includes an adhesive surface and a functional surface. The light-transmitting film is aligned with the drive backplane, and the adhesive surface of the light-transmitting film is attached to the upper end face of each of the more than two LED chips. The light-transmitting film is pressed on each of the more than two LED chips and left for a pre-determined duration, and a release film covering the functional surface is uncovered. The drive backplane covered with the light-transmitting film is heated, to fix the light-transmitting film on each of the more than two LED chips and form the light-transmitting layer.

Optionally, the method further includes the following. A roughness of the light-transmitting layer is changed by optical processing a side of the light-transmitting layer away from each of the more than two LED chips, to enable the light-transmitting layer to have an anti-glare function, an anti-reflection function, an anti-fingerprint function, or a surface hardening function.

Optionally, the drive backplane covered with the light-transmitting film is heated, to fix the light-transmitting film on each of the more than two LED chips and form the light-transmitting layer as follows. A second round of heating is performed on the drive backplane covered with the light-transmitting film for a second heating duration, to fix the light-transmitting film on each of the more than two LED chips, where the second heating duration is longer than the first heating duration.

Optionally, after coating the optical isolation material on the side of the drive backplane carrying the more than two LED chips, to enable the thickness of the optical isolation material to be equal to the height of each of the more than two LED chips, the method further includes removing dust on each of the more than two LED chips by blow washing the drive backplane with an air gun.

Optionally, the drive backplane covered with the light-transmitting film is heated, to fix the light-transmitting film on each of the more than two LED chips and form the light-transmitting layer as follows. The light-transmitting film is provided. The light-transmitting film is aligned with the drive backplane, and the light-transmitting film is attached to the upper end face of each of the more than two LED chips. A downward pressure is applied to an upper surface of the light-transmitting film, and a space between two adjacent LED chips of the more than two LED chips is vacuumized, to fix the light-transmitting film on each of the more than two LED chips and form the light-transmitting layer.

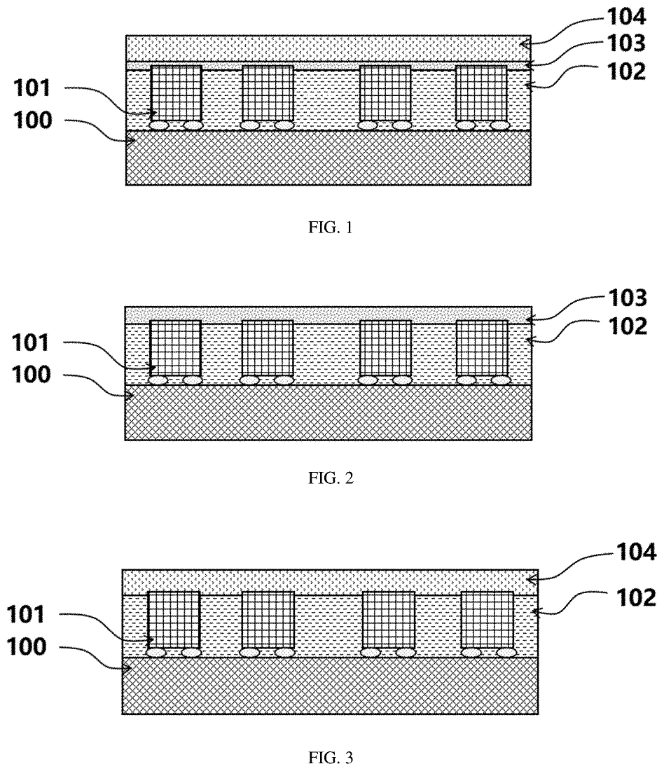

The following will illustrate an LED light-emitting backplane in the disclosure in detail through an implementation, and referring to FIG. 1, the LED light-emitting backplane specifically includes a drive backplane 100.

The drive backplane 100 may be a glass backplane, a printed circuit board (PCB) backplane, or a flexible substrate. The drive backplane 100 includes a drive circuit and an electrode contact material, where the electrode contact material includes titanium (Ti), copper (Cu), indium tin oxide (ITO), nickel (Ni), argentum (Ag), or the like. The drive backplane 100 is mounted with more than two LED chips 101, where each of the more than two LED chips 101 includes a micro LED or a mini LED and can be encapsulated with chips on board (COB). The drive backplane 100 can be provided with LED chips 101 of three colors of red, green, and blue, or can also be only provided with chips of any color of red, green, or blue. An upper end face of each of the more than two LED chips 101 is covered with a light-transmitting layer, and an optical isolation material 102 is filled between the drive backplane 100 and the light-transmitting layer. An upper end face of the optical isolation material 102 has a height shorter than the upper end face of each of the more than two LED chips 101, such that the upper end face of each of the more than two LED chips 101 is exposed from the optical isolation material 102 so as to increase output brightness of each of the more than two LED chips 101.

The optical isolation material 102 consists of a black optical isolation material when the LED light-emitting backplane is directly used as an LED display. The black optical isolation material includes resin, particle-doped resin, chromium oxide, a black polymer material, or the like. The black optical isolation material may have a glossy or matte surface to create different black effects and has a thickness ranging from 30 μm to 50 μm. The optical isolation material 102 may be doped with a thermally conductive particle for improving a heat dissipation performance of the drive backplane 100, where the thermally conductive particle is made of a high thermally conductive ceramic. The optical isolation material 102 consists of a white optical isolation material when the LED light-emitting backplane is used as a liquid crystal display (LCD) backlight. The white optical isolation material includes white glue, a white ink, or a white polymer material and has characteristics of high reflection and low transmission.

The light-transmitting layer includes a semitransparent layer 103 and a high light-transmitting layer 104. The semitransparent layer 103 can be made of resin or glass, and a processing manner of the semitransparent layer 103 includes doping silicon dioxide (SiO₂) powder to change a haze of the semitransparent layer 103. The semitransparent layer 103 has the haze ranging from 30% to 60%, and a light transmittance ranging from 30% to 80%. The high light-transmitting layer 104 is disposed on a side of the semitransparent layer 103 away from each of the more than two LED chips 101. The high light-transmitting layer 104 has a light transmittance greater than 90% and is made of a polymer material, glass, resin, or the like. The high light-transmitting layer 104 may have a smooth surface or a surface with a surface optical processing effect, where the surface optical processing effect includes roughness changing, anti-glare, anti-reflection, anti-fingerprint, surface hardening, or the like, and a specifically processing method includes coating a film or adding an optical diaphragm. Furthermore, the optical surface processing of the high light-transmitting layer 104 and the light transmittance and the haze of the semitransparent layer 103 can be adjusted according to requirements of a light-emitting component. In the implementation, a main effect of the semitransparent layer 103 is to reduce sapphire reflection on a surface of each of the more than two LED chips 101, and to decrease the light transmittance simultaneously. The high light-transmitting layer 104 has two main effects of which one part is to make the high light-transmitting layer 104 have a glossy or matte surface and the other part is to make the high light-transmitting layer 104 have the optical surface processing effect.

The following will illustrate an LED light-emitting backplane in the disclosure in detail through another implementation, and referring to FIG. 2, the LED light-emitting backplane specifically includes a drive backplane 100.

The drive backplane 100 may be a glass backplane, a PCB backplane, or a flexible substrate. The drive backplane 100 includes a drive circuit and an electrode contact material, where the electrode contact material includes Ti, Cu, ITO, Ni, Ag, or the like. The drive backplane 100 is mounted with more than two LED chips 101, where each of the more than two LED chips 101 includes a micro LED or a mini LED and can be encapsulated with COB. The drive backplane 100 can be provided with LED chips 101 of three colors of red, green, and blue, or can also be only provided with chips of any color of red, green, or blue. An upper end face of each of the more than two LED chips 101 is covered with a light-transmitting layer, and an optical isolation material 102 is filled between the drive backplane 100 and the light-transmitting layer. An upper end face of the optical isolation material 102 has a height shorter than the upper end face of each of the more than two LED chips 101, such that the upper end face of each of the more than two LED chips 101 is exposed from the optical isolation material 102 so as to increase output brightness of each of the more than two LED chips 101.

The optical isolation material 102 consists of a black optical isolation material when the LED light-emitting backplane is directly used as an LED display. The black optical isolation material includes resin, particle-doped resin, chromium oxide, a black polymer material, or the like. The black optical isolation material may have a glossy or matte surface to create different black effects and has a thickness of the material ranging from 30 μm to 50 μm. The optical isolation material 102 may be doped with a thermally conductive particle for improving a heat dissipation performance of the drive backplane 100, where the thermally conductive particle is made of a high thermally conductive ceramic. The optical isolation material 102 consists of a white optical isolation material when the LED light-emitting backplane is used as an LCD backlight. The white optical isolation material includes white glue, a white ink, or a white polymer material and has characteristics of high reflection and low transmission.

The light-transmitting layer is a semitransparent layer 103. The semitransparent layer 103 can be made of resin or glass, and a processing manner of the semitransparent layer 103 includes doping SiO₂ powder to change a haze of the semitransparent layer 103. The semitransparent layer 103 has the haze ranging from 30% to 60% and a light transmittance ranging from 30% to 80%. In the implementation, a main effect of the semitransparent layer 103 is to reduce sapphire reflection on a surface of each of the more than two LED chips 101, and to decrease the light transmittance simultaneously. Furthermore, in the implementation, there is no special requirements on optical visual effect, so that a high light-transmitting layer 104 is not required to be disposed on the semitransparent layer 103.

The following will illustrate an LED light-emitting backplane in the disclosure in detail through a yet another implementation, and referring to FIG. 3, the LED light-emitting backplane specifically includes a drive backplane 100.

The drive backplane 100 may be a glass backplane, a PCB backplane, or a flexible substrate. The drive backplane 100 includes a drive circuit and an electrode contact material, where the electrode contact material includes Ti, Cu, ITO, Ni, Ag, or the like. The drive backplane 100 is mounted with more than two LED chips 101, where each of the more than two LED chips 101 includes a micro LED or a mini LED and can be encapsulated with COB. The drive backplane 100 can be provided with LED chips 101 of three colors of red, green, and blue, or can also be only provided with chips of any color of red, green, or blue. An upper end face of each of the more than two LED chips 101 is covered with a light-transmitting layer, and an optical isolation material 102 is filled between the drive backplane 100 and the light-transmitting layer. An upper end face of the optical isolation material 102 has a height shorter than the upper end face of each of the more than two LED chips 101, such that the upper end face of each of the more than two LED chips 101 is exposed from the optical isolation material 102 so as to increase output brightness of each of the more than two LED chips 101.

The optical isolation material 102 consists of a black optical isolation material when the LED light-emitting backplane is directly used as an LED display. The black optical isolation material includes resin, particle-doped resin, chromium oxide, a black polymer material, or the like. The black optical isolation material may have a glossy or matte surface to create different black effects and a thickness ranging from 30 μm to 50 μm. The optical isolation material 102 may be doped with a thermally conductive particle for improving a heat dissipation performance of the drive backplane 100, where the thermally conductive particle is made of a high thermally conductive ceramic. The optical isolation material 102 consists of a white optical isolation material when the LED light-emitting backplane is used as an LCD backlight. The white optical isolation material includes white glue, a white ink, or a white polymer material and has characteristics of high reflection and low transmission.

The light-transmitting layer is a high light-transmitting layer 104. The high light-transmitting layer 104 has a light transmittance greater than 90% and is made of a polymer material, glass, resin, or the like. The high light-transmitting layer 104 may have a smooth surface or a surface with a surface optical processing effect, where the surface optical processing effect includes roughness changing, anti-glare, anti-reflection, anti-fingerprint, surface hardening, or the like, and a specifically processing method includes coating a film or adding an optical diaphragm. Furthermore, the optical surface processing of the high light-transmitting layer 104 and the light transmittance and the haze of the semitransparent layer 103 can be adjusted according to requirements of a light-emitting component. In the implementation, the high light-transmitting layer 104 has two main effects of which one part is to make the high light-transmitting layer 104 have a glossy or matte surface and the other part is to make the high light-transmitting layer 104 have the optical surface processing effect. When the high light-transmitting layer 104 is of a matte surface, the high light-transmitting layer 104 can reduce sapphire reflection on a surface of each of the more than two LED chips 101, so that a semitransparent layer 103 is not required to be disposed.

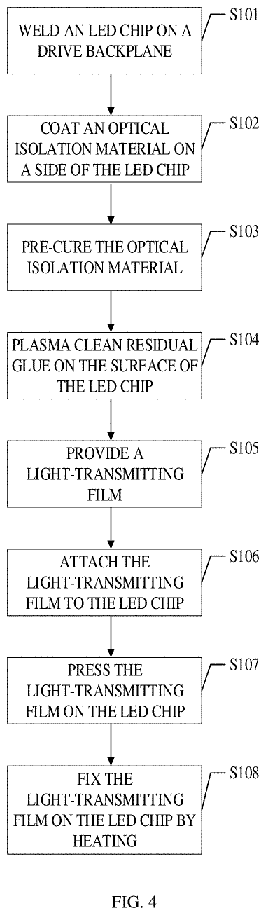

The following will illustrate a manufacturing method for an LED light-emitting backplane in the disclosure in detail through an implementation, and referring to FIG. 4, the method includes the following.

At S101, an LED chip is welded on a drive backplane.

The drive backplane is provided, and more than two LED chips are welded on electrodes of the drive backplane, where the drive backplane may be a glass backplane, a PCB backplane, or a flexible substrate. The LED chip includes a micro LED or a mini LED and can be encapsulated with COB. The electrodes each are made of Ti, Cu, ITO, Ni, Ag, or the like. The drive backplane can be provided with LED chips of three colors of red, green, and blue, or can also be only provided with chips of any color of red, green, or blue.

At S102, an optical isolation material is coated on a side of the LED chip.

The optical isolation material is coated on a side of the drive backplane carrying the LED chip, such that a thickness of the optical isolation material is equal to a height of the LED chip. The LED chip will be a little higher than the optical isolation material since the optical isolation material may be contracted during subsequent pre-curing. Therefore, the thickness of the optical isolation material is required to be equal to the height of the LED chip in the operations at S102, where the optical isolation material consists of a black optical isolation material or a white optical isolation material. The optical isolation material consists of the black optical isolation material when the LED light-emitting backplane is directly used as an LED display. The optical isolation material consists of the white optical isolation material when the LED light-emitting backplane is used as an LCD backlight.

At S103, the optical isolation material is pre-cured.

The backplane provided with the optical isolation material is heated in a 160° C. environment for 10 minutes, to pre-cure the optical isolation material. In the implementation, pre-curing the optical isolation material is beneficial to performing plasma cleaning on a surface of the LED chip in subsequent operations.

At S104, residual glue on the surface of the LED chip is plasma cleaned.

The surface of the LED chip is plasma cleaned. In the implementation, the residual glue of a part of the optical isolation material may be remained on the surface of the LED chip during arrangement of the optical isolation material, and the residual glue on the surface of the LED chip can be effectively removed by plasma cleaning.

At S105, a light-transmitting film is provided.

The light-transmitting film is provided and includes an adhesive surface.

At S106, the light-transmitting film is attached to the LED chip.

The light-transmitting film is aligned with the drive backplane, a release film on the adhesive surface is uncovered, and the adhesive surface of the light-transmitting film is attached to an upper end face of the LED chip.

At S107, the light-transmitting film is pressed on the LED chip.

The drive backplane attached with the light-transmitting film is putted into a pressing machine, to press the light-transmitting film on the LED chip. The drive backplane pressed with the light-transmitting film is placed in a room-temperature environment and left for 10 minutes, and then the release film covering a functional surface is uncovered.

At S108, the light-transmitting film is fixed on the LED chip by heating.

The drive backplane covered with the light-transmitting film is heated with a heating temperature of 160° C., to fix the light-transmitting film on the LED chip and form the light-transmitting layer.

At S108, the light-transmitting film is fixed on the LED chip by heating as follows.

The drive backplane after removal of the residual glue is heated in the 160° C. environment for 60 minutes, to fix the light-transmitting film on the LED chip and form the light-transmitting layer. Furthermore, a roughness of the light-transmitting layer is changed by optical processing a side of the light-transmitting layer away from the LED chip, to enable the light-transmitting layer to have an anti-glare function, an anti-reflection function, an anti-fingerprint function, or a surface hardening function.

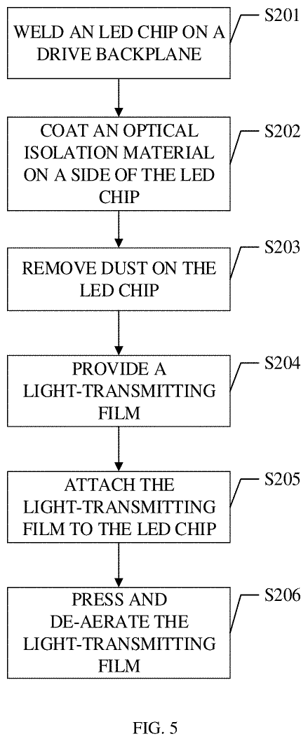

The following will illustrate a manufacturing method for an LED light-emitting backplane in the disclosure in detail through another implementation, and referring to FIG. 5, the method includes the following.

At S201, an LED chip is welded on a drive backplane.

The drive backplane is provided, and more than two LED chips are welded on electrodes of the drive backplane, where the drive backplane may be a glass backplane, a PCB backplane, or a flexible substrate. The LED chip includes a micro LED or a mini LED and can be encapsulated with COB. The electrodes each are made of Ti, Cu, ITO, Ni, Ag, or the like. The drive backplane can be provided with LED chips of three colors of red, green, and blue, or can also be only provided with chips of any color of red, green, or blue.

At S202, an optical isolation material is coated on a side of the LED chip.

The optical isolation material is coated on a side of the drive backplane carrying the LED chip, such that a thickness of the optical isolation material is equal to a height of the LED chip. The LED chip will be a little higher than the optical isolation material since the optical isolation material may be contracted during subsequent pre-curing. Therefore, the thickness of the optical isolation material is required to be equal to the height of the LED chip in the operations at S202, where the optical isolation material consists of a black optical isolation material or a white optical isolation material. The optical isolation material consists of the black optical isolation material when the LED light-emitting backplane is directly used as an LED display. The optical isolation material consists of the white optical isolation material when the LED light-emitting backplane is used as an LCD backlight.

At S203, dust on the LED chip is removed.

The dust on the LED chip is removed by blow washing the drive backplane with an air gun.

At S204, a light-transmitting film is provided.

The light-transmitting film is provided. Light-transmitting films with different functions can be used according to display-effect requirements of users.

At S205, the light-transmitting film is attached to the LED chip.

The light-transmitting film is aligned with the drive backplane, and the light-transmitting film is attached to an upper end face of the LED chip.

At S206, the light-transmitting film is pressed and de-aerated.

A downward pressure is applied to an upper surface of the light-transmitting film, and a space between two adjacent LED chips is vacuumized, to fix the light-transmitting film on the LED chip and form the light-transmitting layer. Since much air may be left in the space between the two adjacent LED chips after the light-transmitting film is attached to the upper end face of the LED chip, it is required to vacuumize the space between the two adjacent LED chips, fill the space between the LEDs with the light-transmitting film, and make no air between the light-transmitting film and the driving backplane as much as possible.

The reference term “an embodiment”, “some embodiments”, “exemplary embodiment”, “implementation”, “specific implementation”, or “some implementations” referred to herein means that a particular feature, structure, material, or characteristic described in conjunction with the embodiment or implementation may be contained in at least one embodiment or implementation of the present disclosure. In the specification, the exemplary expression of the above terms does not necessarily refer to the same embodiment or implementation. The particular feature, structure, material, or characteristic described may be properly combined in any one or more embodiments or implementations.

The above is only an implementation of the disclosure and is not intended to limit the scope of protection of the disclosure. Any modification, equivalent arrangements, and improvement made within the spirit and principles of the disclosure shall be included in the scope of protection of the disclosure.

What is claimed is:

1. A light-emitting diode (LED) light-emitting backplane, comprising:
a drive backplane mounted with more than two LED chips, an upper end face of each of the more than two LED chips being covered with a light-transmitting layer, an optical isolation material being filled between the drive backplane and the light-transmitting layer.

2. The LED light-emitting backplane of claim 1, wherein the light-transmitting layer comprises a semitransparent layer.

3. The LED light-emitting backplane of claim 2, wherein the semitransparent layer has a light transmittance ranging from 30% to 80%.

4. The LED light-emitting backplane of claim 1, wherein the light-transmitting layer comprises a high light-transmitting layer.

5. The LED light-emitting backplane of claim 4, wherein the high light-transmitting layer has a light transmittance greater than 90%.

6. The LED light-emitting backplane of claim 1, wherein the light-transmitting layer comprises a semitransparent layer and a high light-transmitting layer.

7. The LED light-emitting backplane of claim 6, wherein the high light-transmitting layer has a light transmittance greater than the semitransparent layer.

8. The LED light-emitting backplane of claim 6, wherein the semitransparent layer covers each of the more than two LED chips, and the high light-transmitting layer is disposed on a side of the semitransparent layer away from each of the more than two LED chips.

9. The LED light-emitting backplane of claim 1, wherein the optical isolation material has a height shorter than each of the more than two LED chips.

10. The LED light-emitting backplane of claim 1, wherein the optical isolation material consists of a black optical isolation material.

11. The LED light-emitting backplane of claim 10, wherein the optical isolation material is doped with a thermally conductive particle.

12. The LED light-emitting backplane of claim 1, wherein the optical isolation material consists of a white optical isolation material.

13. A manufacturing method for a light-emitting diode (LED) light-emitting backplane, comprising:
providing a drive backplane, and welding more than two LED chips on electrodes of the drive backplane;
coating an optical isolation material on a side of the drive backplane carrying the more than two LED chips, to enable a thickness of the optical isolation material to be equal to a height of each of the more than two LED chips; and
forming a light-transmitting layer by covering upper end faces of all the more than two LED chips with a pre-prepared light-transmitting film and fixing the light-transmitting film on each of the more than two LED chips.

14. The manufacturing method for an LED light-emitting backplane of claim 13, wherein after coating the optical isolation material on the side of the drive backplane carrying the more than two LED chips, and before covering the upper end faces of all the more than two LED chips with the pre-prepared light-transmitting film, the method further comprises:
plasma cleaning a surface of each of the more than two LED chips.

15. The manufacturing method for an LED light-emitting backplane of claim 14, wherein after coating the optical isolation material on the side of the drive backplane carrying the more than two LED chips, and before plasma cleaning the surface of each of the more than two LED chips, the method further comprises:
performing a first round of heating on the drive backplane for a first heating duration, to pre-cure the optical isolation material on the drive backplane.

16. The manufacturing method for an LED light-emitting backplane of claim 15, wherein forming the light-transmitting layer by covering the upper end faces of all the more than two LED chips with the pre-prepared light-transmitting film and fixing the light-transmitting film on each of the more than two LED chips comprises:
providing the light-transmitting film, aligning the light-transmitting film with the drive backplane, and attaching the light-transmitting film to the upper end face of each of the more than two LED chips;
pressing the light-transmitting film on each of the more than two LED chips; and
heating the drive backplane covered with the light-transmitting film, to fix the light-transmitting film on each of the more than two LED chips and form the light-transmitting layer.

17. The manufacturing method for an LED light-emitting backplane of claim 16, further comprising:
changing a roughness of the light-transmitting layer by optical processing a side of the light-transmitting layer away from each of the more than two LED chips, to enable the light-transmitting layer to have an anti-glare function, an anti-reflection function, an anti-fingerprint function, or a surface hardening function.

18. The manufacturing method for an LED light-emitting backplane of claim 16, wherein heating the drive backplane covered with the light-transmitting film, to fix the light-transmitting film on each of the more than two LED chips and form the light-transmitting layer comprises:
performing a second round of heating on the drive backplane covered with the light-transmitting film for a second heating duration, to fix the light-transmitting film on each of the more than two LED chips, wherein the second heating duration is longer than the first heating duration.

19. The manufacturing method for an LED light-emitting backplane of claim 13, wherein after coating the optical isolation material on the side of the drive backplane carrying the more than two LED chips, to enable the thickness of the optical isolation material to be equal to the height of each of the more than two LED chips, the method further comprises:
removing dust on each of the more than two LED chips by blow washing the drive backplane with an air gun.

20. The manufacturing method for an LED light-emitting backplane of claim 19, wherein heating the drive backplane covered with the light-transmitting film, to fix the light-transmitting film on each of the more than two LED chips and form the light-transmitting layer comprises:
providing the light-transmitting film;
aligning the light-transmitting film with the drive backplane, and attaching the light-transmitting film to the upper end face of each of the more than two LED chips; and
applying a downward pressure to an upper surface of the light-transmitting film, and vacuumizing a space between two adjacent LED chips of the more than two LED chips, to fix the light-transmitting film on each of the more than two LED chips and form the light-transmitting layer.
